(19) United States
(12) Patent Application Publication
(10) Pub. No.: US 2011/0026204 A1
(43) Pub. Date: Feb. 3, 2011

(54) HINGE STRUCTURE CAPABLE OF ACCOMMODATING A CABLE AND RELATED ELECTRONIC DEVICE

(76) Inventor: Chun-Fei Yang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/843,053

(22) Filed: Jul. 26, 2010

(30) Foreign Application Priority Data
Aug. 3, 2009 (TW) 098126062

(51) Int. Cl. H05K 7/00; E05D 11/00

(52) U.S. Cl. 361/679.01; 16/223

(57) ABSTRACT

A hinge structure for accommodating a cable includes a main body. An accommodating space is formed inside the main body. A hole connecting to the accommodating space is formed on the main body. The cable passes through the hole so as to be accommodated inside the accommodating space partly. The hinge structure further includes a fixing component disposed on a side of the main body and connected to a first component, and a pivoting component connected with the main body and a second component in a rotatable manner, so that the second component can rotate relative to the first component. The hinge structure further includes a covering component for covering the hole on the main body so as to hold the cable inside the accommodating space.

### BACKGROUND OF THE INVENTION

1. Field of the Invention

The present invention relates to a hinge structure and a related electronic device, and more particularly, to a hinge structure capable of accommodating a cable and a related electronic device.

2. Description of the Prior Art

In assembly of a portable electronic device, installing a hinge structure between a liquid crystal display (LCD) monitor and a host spends labor hours. Generally, a conventional assembly of the hinge structure is as follows. Passing a cable through a hole on the hinge structure, connecting two ends of the cable with corresponding connectors, and electrically connecting the connectors installed on the two ends of the cable with the LCD monitor and the host of the portable electronic device respectively. Due to limitation of the hole's dimensions, the cable has to pass through the hole on the hinge structure first, and then the corresponding connectors can be installed on the two ends of the cable for electrically connecting to the portable electronic device. That is to say, the connectors cannot be installed on the cable before accommodating the cable inside the hinge structure. The connectors have to be installed on the cable after the cable passes through the hole on the hinge structure. Therefore, it increases difficulty of assembly of the hinge structure and spends more labor hours, and manufacturing yield of the hinge structure can not be increased effectively. In addition, the cable is exposed on a gap between the LCD monitor ad the host partly when the LCD monitor rotates relative to the host, so that appearance of the electronic device is inaesthetic and the exposed cable is broken easily. Thus, design of a hinge structure with aesthetic appearance and capable of assembling a cable easily is an important issue in the mechanical design industry.

### SUMMARY OF THE INVENTION

The present invention provides a hinge structure capable of accommodating a cable and a related electronic device for solving above drawbacks.

According to the claimed invention, a hinge structure includes a main body, an accommodating space being formed inside the main body, a hole connecting to the accommodating space being formed on the main body, and a cable passing through the hole so as to be accommodated inside the accommodating space partly, a fixing component disposed on a side of the main body and connected to a first component, a pivoting component connected with the main body and a second component in a rotatable manner so that the second component rotates relative to the first component, and a covering component for covering the hole on the main body so as to hold the cable inside the accommodating space.

According to the claimed invention, the hinge structure further includes a structural component disposed on the pivoting component for connecting with the pivoting component and the second component.

According to the claimed invention, the main body is a pillar structure.

According to the claimed invention, the covering component is an arc structure for covering the pillar structure.

According to the claimed invention, the hole is a slot.

According to the claimed invention, at least one notch is formed on the main body, and at least one protrusion is formed on an end of the covering component for wedging inside the notch so as to hold the covering component on the main body.

According to the claimed invention, the covering component is made of elastic material for covering the main body in an elastically deformable manner.

According to the claimed invention, the covering component is made of non-elastic material for covering the main body by welding or gluing.

According to the claimed invention, an electronic device includes a first component, a second component, a cable for electrically connecting to the first component and the second component, and a hinge structure for pivoting to the first component and the second component. The hinge structure includes a main body, an accommodating space being formed inside the main body, a hole connected to the accommodating space being formed on the main body, and the cable passing through the hole so as to be accommodated inside the accommodating space partly, a fixing component disposed on a side of the main body and connected to the first component, a pivoting component connected with the main body and the second component in a rotatable manner so that the second component rotates relative to the first component, and a covering component for covering the hole on the main body so as to hold the cable inside the accommodating space.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a hinge structure according to a preferred embodiment of the present invention.

FIG. 2 is an exploded diagram of the hinge structure in another view according to the preferred embodiment of the present invention.

FIG. 3 is a bottom view of a main body and a covering component according to the preferred embodiment of the present invention.

FIG. 4 is a lateral view of the main body and the covering component according to the preferred embodiment of the present invention.

### DETAILED DESCRIPTION

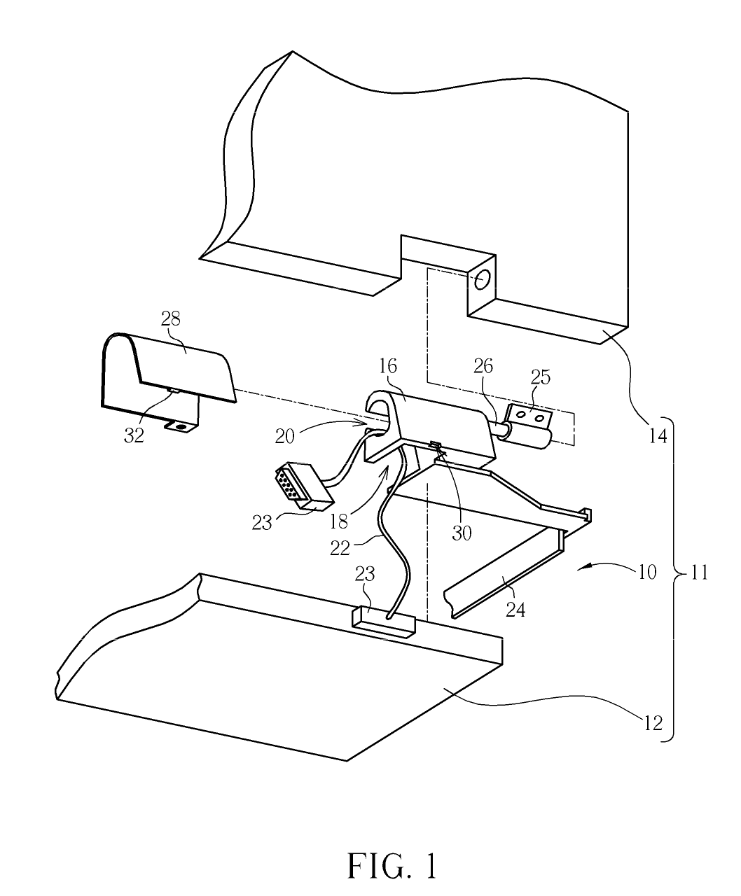

Please refer to FIG. 1. FIG. 1 is a diagram of a hinge structure 10 according to a preferred embodiment of the present invention. The hinge structure 10 is for pivoting to a first component 12 and a second component 14 of an electronic device 11. The electronic device 11 can be a portable electronic device, such as a notebook computer, a personal digital assistant (PDA)))))), a smart mobile phone, and so on. The first component 12 can be a host of the electronic device 11, and the second component 14 can be a LCD monitor of the electronic device 11. The hinge structure 10 includes a main body 16. An accommodating space 18 is formed inside the main body 16, and a hole 20 connecting to the accommodating space 18 is formed on the main body 16. The hole 20 can be a slot.

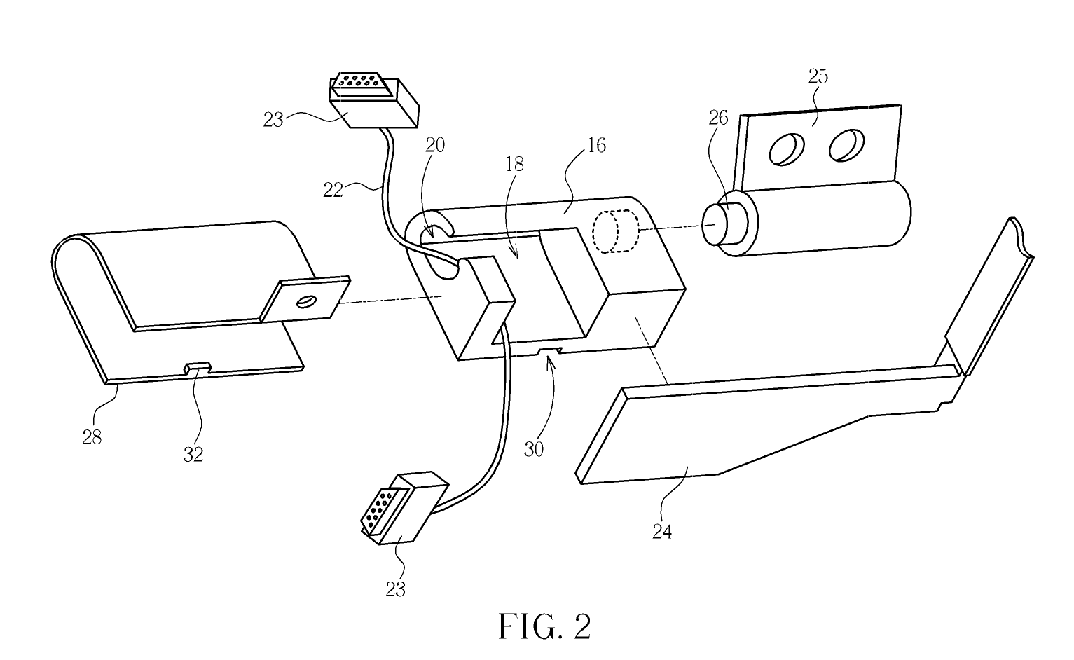

Please refer to FIG. 1 and FIG. 2. FIG. 2 is an exploded diagram of the hinge structure 10 in another view according to the preferred embodiment of the present invention. The hinge structure 10 can be for accommodating a cable 22 passing through the hole 20 so as to be accommodated inside the accommodating space 18 partly. Two connectors 23 are installed on two ends of the cable 22, respectively. The cable 22 and the connectors 23 are for electrically connecting with the first component 12 and the second component 14 so as to transmit a signal between the first component 12 and the second component 14.

The hinge structure 10 further includes a fixing component 24 disposed on a side of the main body 16 and for connecting to the first component 12, a pivoting component 26 connected with the main body 16 and the second component 14 in a pivotable manner so that the second component 14 can rotate relative to the first component 12, and a covering component 28 for covering the hole 20 on the main body 16 so as to hold the cable 22 inside the accommodating space 18. The main body 16 can be a pillar structure, such as a rectangular pillar structure or a column pillar structure. A shape of the covering component 28 corresponds to a shape of the main body 16, so that the covering component 28 can be an arc structure for covering the main body 16.

The hinge structure 10 further includes a structural component 25 disposed on the pivoting component 26 for connecting to the second component 14. The pivoting component 26 can be connected with the main body 16 and the second component 14 in the pivotable manner via the structural component 25. For example, the structural component 25 can be fixed on the pivoting component 26. By connecting the pivoting component 26 to the main body 16 in the pivotable manner, the second component 14 can rotate relative to the first component 12. In addition, the structural component 25 can further be connected to the pivoting component 26 in the pivotable manner. By fixing the pivoting component 26 on the main body 16, the second component 14 can also rotate relative to the first component 12. Combination of the pivoting component 26 and the structural component 25 is not limited as the embodiment mentioned above, and it depends on actual demand.

The covering component 28 can be made of elastic material, such as metal material or plastic material. When the covering component 28 covers the hole 20 on the main body 16, the covering component 28 can cover the main body 16 in an elastically deformable manner. The covering component 28 can further be made of non-elastic material, such as non-elastic metal material or plastic material. The covering component 28 can be welded or glued on the main body 16. The metal material can be zinc alloy material or aluminum alloy material, and the plastic material can be polycarbonate material or acrylic material.

Furthermore, at least one notch 30 can be formed on the main body 16, and at least one protrusion 32 can be formed on an end of the covering component 28 for wedging inside the notch 30, so as to fix the covering component 28 on the main body 16. Combination of the main body 16 and the covering component 28 is not limited to the combination of the protrusion 32 and the notch 30. For example, the covering component 28 can be welded, glued, or wedged on the main body 16, which means the wedge 32 and the notch 30 can be designed selectively.

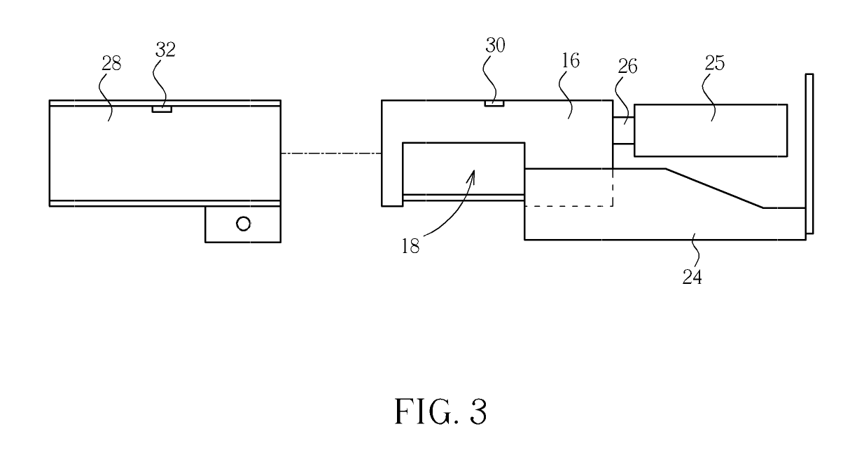

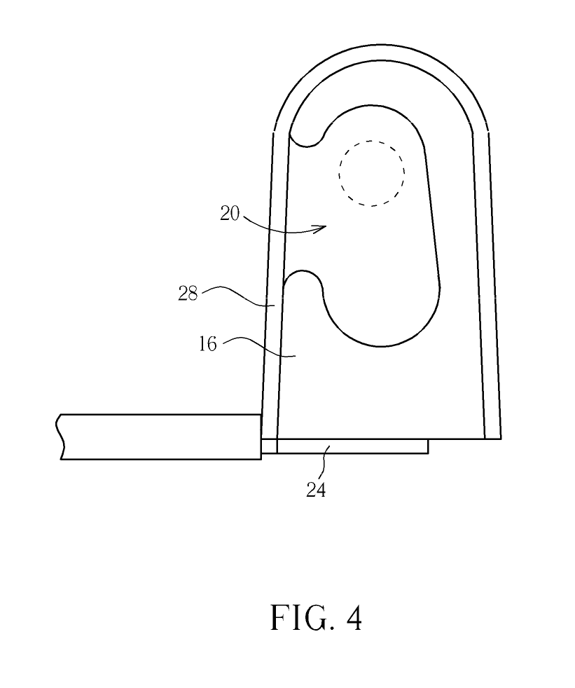

Please refer to FIG. 3 and FIG. 4. FIG. 3 is a bottom view of the main body 16 and the covering component 28 according to the preferred embodiment of the present invention. FIG. 4 is a lateral view of the main body 16 and the covering component 28 according to the preferred embodiment of the present invention. When the covering component 28 covers the main body 16, the hole 20 on the main body 16 is covered by the covering component 28. That is to say, when the second component 14 rotates relative to the first component 12, the hole 20 and the cable 22 are not exposed on a gap between the second component 14 and the first component 12 due to the covering component 28. In addition, the accommodating space 18 is as a tunnel formed inside the main body 16, which passes two sides of the main body 16 thoroughly. When installing the hinge structure 10 on the electronic device 11, the cable 22 can be accommodated inside the accommodating space 18 of the main body 16 partly via the hole 20. The connectors 23 disposed on the two ends of the cable 22 have not to pass through the accommodating space 18 via the hole 20, which means the cable 22 can be accommodated inside the hinge structure 10 by directly putting middle of the cable 22 into the accommodating space 18 of the main body 16 via the hole 20. Therefore, the conventional drawback that the connectors have to be installed on the cable after the cable passes through the hole on the hinge structure can be overcome. Afterward, the covering component 28 can be for covering the main body 16. Because the hole 20 is covered by the covering component 28, the cable 22 can be held inside the accommodating space 18 of the main body 16. The cable 22 can pass through the accommodating space 18 and be held inside the main body 16 easily so as to increase convenience of assembly of the cable 22 and the hinge structure 10 effectively.

In addition, because the covering component 28 covers on the main body 16, after the cable 22 passes through the hinge structure 10 and is electrically connected with the first component 12 and the second component 14, the covering component 28 not only can be for holding the cable 22 inside the main body 16, but also can hide the cable 22 inside the hinge structure 10 so as to prevent an inaesthetic appearance of exposing the cable 22 exteriorly and to prevent the cable 22 from being broken easily. Furthermore, the covering component 28 can be designed with any kinds of surface processing technology artistically. For example, a surface of the covering component 28 can be processed by polishing, carving, or painting, and it depends on design demand.

Comparing to the prior art, the hinge structure and the related electronic device of the present invention utilizes the covering component to hold the cable inside the main body, which can improve inconvenience of assembly of the conventional hinge structure, and can further economize labor hours. Therefore, the present invention has low assembly complexity and high manufacturing yield, so as to enhance assembly convenience and aesthetic feeling of the hinge structure effectively.

Those skilled in the art will readily observe that numerous modifications and alterations of the device and method may be made while retaining the teachings of the invention.

What is claimed is:

1. A hinge structure comprising:
a main body, an accommodating space being formed inside the main body, a hole connecting to the accommodating space being formed on the main body, and a cable passing through the hole so as to be accommodated inside the accommodating space partly;
a fixing component disposed on a side of the main body and connected to a first component;
a pivoting component connected with the main body and a second component in a rotatable manner so that the second component rotates relative to the first component; and
a covering component for covering the hole on the main body so as to hold the cable inside the accommodating space.

2. The hinge structure of claim 1 further comprising:
a structural component disposed on the pivoting component for connecting with the pivoting component and the second component.

3. The hinge structure of claim 1, wherein the main body is a pillar structure.

4. The hinge structure of claim 3, wherein the covering component is an arc structure for covering the pillar structure.

5. The hinge structure of claim 1, wherein the hole is a slot.

6. The hinge structure of claim 1, wherein at least one notch is formed on the main body, and at least one protrusion is formed on an end of the covering component for wedging inside the notch so as to hold the covering component on the main body.

7. The hinge structure of claim 1, wherein the covering component is made of elastic material for covering the main body in an elastically deformable manner.

8. The hinge structure of claim 1, wherein the covering component is made of non-elastic material.

9. The hinge structure of claim 1, wherein the covering component is welded on the main body.

10. The hinge structure of claim 1, wherein the covering component is glued on the main body.

11. An electronic device comprising:
a first component;
a second component;
a cable for electrically connecting to the first component and the second component; and
a hinge structure for pivoting to the first component and the second component, the hinge structure comprising:
a main body, an accommodating space being formed inside the main body, a hole connected to the accommodating space being formed on the main body, and the cable passing through the hole so as to be accommodated inside the accommodating space partly;
a fixing component disposed on a side of the main body and connected to the first component;
a pivoting component connected with the main body and the second component in a rotatable manner so that the second component rotates relative to the first component; and
a covering component for covering the hole on the main body so as to hold the cable inside the accommodating space.

12. The electronic device of claim 11, wherein the hinge structure further comprises a structural component disposed on the pivoting component for connecting with the pivoting component and the second component.

13. The electronic device of claim 11, wherein the main body is a pillar structure.

14. The electronic device of claim 13, wherein the covering component is an arc structure for covering the pillar structure.

15. The electronic device of claim 11, wherein at least one notch is formed on the main body, and at least one protrusion is formed on an end of the covering component for wedging inside the notch so as to hold the covering component on the main body.

16. The electronic device of claim 11, wherein the covering component is made of elastic material for covering the main body in an elastically deformable manner.

17. The electronic device of claim 11, wherein the covering component is welded or glued on the main body.

18. The electronic device of claim 11, wherein the first component is a host.

19. The electronic device of claim 11, wherein the second component is a liquid crystal display (LCD) monitor.

20. The electronic device of claim 11 further comprising:
a connector installed on an end of the cable.
